(19) United States
(12) Patent Application Publication
(10) Pub. No.: US 2022/0227255 A1
(43) Pub. Date: Jul. 21, 2022

(54) INFORMATION PROCESSING DEVICE, INFORMATION PROCESSING METHOD, AND PROGRAM

(71) Applicant: HONDA MOTOR CO., LTD., Minato-ku, Tokyo (JP)

(72) Inventor: Yoshikazu Nishida, Wako-shi (JP)

(21) Appl. No.: 17/611,580

(22) PCT Filed: May 21, 2019
(86) PCT No.: PCT/JP2019/020005

§ 371 Date: Nov. 16, 2021

(51) Int. Cl. B60L 58/16; G07C 5/00; G07C 5/10; H01M 10/48

(52) U.S. Cl. CPC B60L 58/16; G07C 5/008; H01M 2220/20; H01M 10/48; G07C 5/10

(57) ABSTRACT

An information processing device includes a reception unit configured to receive vehicle information about a vehicle equipped with a secondary battery and secondary battery information about the secondary battery transmitted from the vehicle, an analysis unit configured to generate analysis information by analyzing a relationship between the vehicle information and each type of the secondary battery information, and a provision unit configured to provide provision information based on the analysis information.

### TECHNICAL FIELD

The present invention relates to an information processing device, an information processing method, and a program.

### BACKGROUND ART

Secondary batteries mounted in electric vehicles deteriorate due to use thereof. Conventionally, there is technology for providing a driver with information about charging and deterioration of a secondary battery in an electric vehicle (see, for example, Patent Literature 1 and 2).

### CITATION LIST

### Patent Literature

### [Patent Literature 1]

Japanese Unexamined Patent Application, First Publication No. 2011-229324

### [Patent Literature 2]

Japanese Unexamined Patent Application, First Publication No. 2011-55620

### SUMMARY OF INVENTION

### Technical Problem

A secondary battery mounted and used in an electric vehicle may be reused for other applications such as a secondary battery that is mounted in another electric vehicle, a stationary battery, and the like after deterioration. When the reuse of the secondary battery is taken into account, the performance at the time of reuse of the secondary battery is an important factor. However, while the secondary battery is mounted in an electric vehicle and is in use, it is difficult to obtain information about the performance of the secondary battery at the time of reuse.

The present invention has been made in consideration of the above circumstances and provides an information processing device, an information processing method, and a program capable of obtaining information about the performance of a secondary battery at the time of reuse.

### Solution to Problem

An information processing device, an information processing method, and a program according to the present invention adopt the following configurations.

(1): According to an aspect of the present invention, there is provided an information processing device including: a reception unit configured to receive vehicle information about a vehicle equipped with a secondary battery and secondary battery information about the secondary battery transmitted from the vehicle; an analysis unit configured to generate analysis information by analyzing a relationship between the vehicle information and each type of the secondary battery information; and a provision unit configured to provide provision information based on the analysis information.

(2): In the above-described aspect (1), the secondary battery information includes information about at least one of a manufacturer of the secondary battery, the number of times the secondary battery has been charged, and a period during which the secondary battery has been mounted in the vehicle.

(3): In the above-described aspect (1), the vehicle information includes a type of the vehicle.

(4): In any one of the above-described aspects (1) to (3), the analysis unit generates the analysis information for each type of the vehicle.

(5): In any one of the above-described aspects (1) to (4), the provision information is about durability of the secondary battery after a prescribed period.

(6): In the above-described aspect (5), the provision unit provides durability for a plurality of types of prescribed periods.

(7): In any one of the above-described aspects (1) to (6), the vehicle information includes information about an owner of the vehicle, and, when the number of owners is two or more, the analysis unit generates the analysis information for each of the owners.

(8): In any one of the above-described aspects (1) to (7), when the secondary battery has been mounted in a plurality of vehicles, the analysis unit generates the analysis information for each of the plurality of vehicles.

(9): According to an aspect of the present invention, there is provided an information processing method including: receiving, by a computer, vehicle information about a vehicle equipped with a secondary battery and secondary battery information about the secondary battery transmitted from the vehicle; generating, by the computer, analysis information by analyzing a relationship between the vehicle information and the secondary battery information; and providing, by the computer, provision information based on the analysis information.

(10): According to an aspect of the present invention, there is provided a program for causing a computer to: receive vehicle information about a vehicle equipped with a secondary battery and secondary battery information about the secondary battery transmitted from the vehicle; generate analysis information by analyzing a relationship between the vehicle information and the secondary battery information; and provide provision information based on the analysis information.

### Advantageous Effects of Invention

According to (1) to (10), it is possible to obtain information about the performance of a secondary battery at the time of reuse.

### BRIEF DESCRIPTION OF DRAWINGS

FIG. 1 is a diagram showing an example of a configuration of an information processing system 1 according to a first embodiment.

FIG. 2 is a diagram showing an example of a configuration of a vehicle 10.

FIG. 3 is a diagram showing an example of collected data 152.

FIG. 4 is a diagram showing an example of a configuration of a cabin of the vehicle 10.

FIG. 5 is a diagram showing an example of analysis data 154.

FIG. 6 is a diagram showing an example of provision data 156.

FIG. 7 is a flowchart showing an example of a process executed by an information processing device 100.

FIG. 8 is a diagram showing an example of a screen displayed on a terminal device 300.

FIG. 9 is a diagram showing an example of collected data 162 of a second embodiment.

FIG. 10 is a diagram showing an example of analysis data 164 of the second embodiment.

FIG. 11 is a diagram showing an example of collected data 172 of a third embodiment.

FIG. 12 is a diagram showing an example of analysis data 174 of the third embodiment.

FIG. 13 is a diagram showing an example of an image displayed on a display device 60.

### DESCRIPTION OF EMBODIMENTS

Hereinafter, embodiments of an information processing device, an information processing method, and a program of the present invention will be described with reference to the drawings. The following embodiments do not limit the present invention covered by claims. Also, not all combinations of features described in the embodiments are necessary for solutions of the present invention. Although a vehicle 10 is assumed to be an electric vehicle, the vehicle 10 may be a hybrid vehicle or a fuel cell vehicle as long as it is a vehicle equipped with a secondary battery that supplies electric power for traveling of the vehicle 10.

### First Embodiment

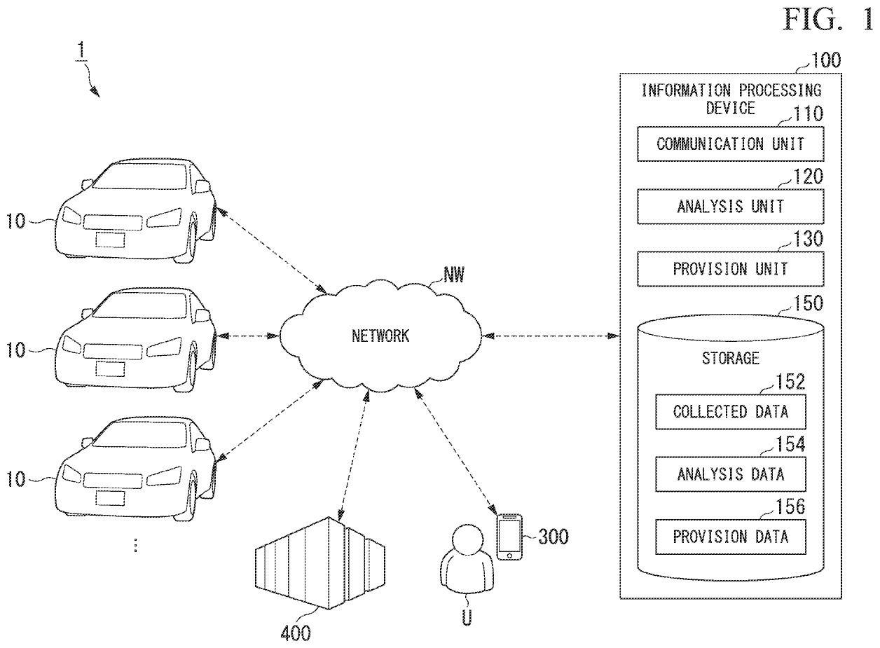

FIG. 1 is a diagram showing an example of a configuration of an information processing system 1 according to a first embodiment. As shown in FIG. 1, the information processing system 1 includes a plurality of vehicles 10 and an information processing device 100. The information processing system 1 requests information about performance when a battery (which is hereinafter assumed to be synonymous with a secondary battery) mounted in the vehicle 10 is reused and provides the information to the vehicle 10, a terminal device 300 owned by a user U, a used vehicle sales business server 400 of a used vehicle sales business operator, and the like.

The information processing device 100 generates data related to a battery to be provided to the terminal device 300 owned by the user U and/or the used vehicle sales business server 400 on the basis of information transmitted by the plurality of vehicles 10. The vehicle 10 communicates with the information processing device 100 via a network NW. The network NW includes, for example, the Internet, a wide area network (WAN), a local area network (LAN), a provider device, a radio base station, and the like.

### [Vehicle 10]

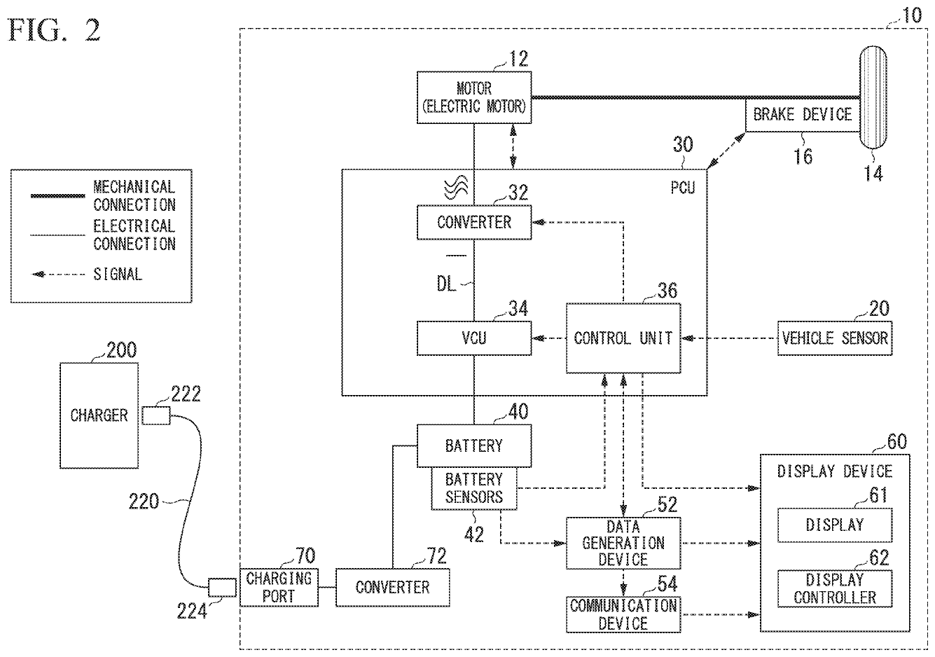

FIG. 2 is a diagram showing an example of a configuration of the vehicle 10. As shown in FIG. 2, the vehicle 10 includes, for example, a motor 12, drive wheels 14, a brake device 16, a vehicle sensor 20, a power control unit (PCU) 30, a battery 40, battery sensors 42 such as a voltage sensor, a current sensor, and a temperature sensor, a data generation device 52, a communication device 54, a display device 60, a charging port 70, and a converter 72.

The motor 12 is, for example, a three-phase alternating current (AC) electric motor. A rotor of the motor 12 is connected to the drive wheels 14. The motor 12 outputs motive power to the drive wheels 14 using electric power that is supplied. Also, the motor 12 generates electric power using kinetic energy of the vehicle when the vehicle is decelerated.

The brake device 16 includes, for example, a brake caliper, a cylinder that transfers hydraulic pressure to the brake caliper, and an electric motor that generates hydraulic pressure in the cylinder. The brake device 16 may include a mechanism that transfers hydraulic pressure generated by the operation of the brake pedal to the cylinder via a master cylinder as a backup. Also, the brake device 16 is not limited to the above-described configuration and may be an electronically controlled hydraulic brake device that transfers the hydraulic pressure of the master cylinder to the cylinder.

The vehicle sensor 20 includes an accelerator opening degree sensor, a vehicle speed sensor, and a brake depression amount sensor. The accelerator opening degree sensor is attached to an accelerator pedal, which is an example of an operation element for receiving an acceleration instruction from a driver, detects an amount of operation of the accelerator pedal, and outputs the detected amount of operation as an accelerator opening degree to the control unit 36. The vehicle speed sensor includes, for example, a wheel speed sensor and a speed calculator attached to each wheel and combines wheel speeds detected by wheel speed sensors to derive the speed of the vehicle (a vehicle speed) and outputs the derived speed to the control unit 36 and the display device 60. The brake depression amount sensor is attached to the brake pedal, detects the amount of operation of the brake pedal, and outputs the detected amount of operation as an amount of brake depression to the control unit 36.

The PCU 30 includes, for example, a converter 32, a voltage control unit (VCU) 34, and the control unit 36. Also, a group of the above components is configured as the PCU 34 as only an example and these components may be arranged in a distributed form.

The converter 32 is, for example, an AC-direct current (DC) converter. A DC side terminal of the converter 32 is connected to a DC link DL. The battery 40 is connected to the DC link DL via the VCU 34. The converter 32 converts an AC generated by the motor 12 into a DC and outputs the DC to the DC link DL.

The VCU 34 is, for example, a DC-DC converter. The VCU 34 boosts electric power supplied by the battery 40 and outputs the boosted electric power to the DC link DL.

The control unit 36 includes, for example, a motor control unit, a brake control unit, and a battery/VCU control unit. The motor control unit, the brake control unit, and the battery/VCU control unit may be replaced with separate control devices such as a motor ECU, a brake ECU, and a battery ECU.

The motor control unit controls the motor 12 on the basis of an output of the vehicle sensor 20. The brake control unit controls the brake device 16 on the basis of an output of the vehicle sensor 20. The battery/VCU control unit calculates a state of charge (SOC) (hereinafter also referred to as a “battery charge rate”) of the battery 40 on the basis of an output of the battery sensor 42 attached to the battery 40. In battery/VCU control, the calculated SOC is output to the VCU 34 and the data generation device 52. The VCU 34 causes a voltage of the DC link DL to be raised in accordance with an instruction from the battery/VCU control unit.

The battery/VCU control unit confirms that the battery 40 has been charged on the basis of an output of the battery sensor. The battery/VCU control unit outputs charging execution information to the data generation device 52 when the battery 40 has been charged.

The battery 40 is, for example, a secondary battery such as a lithium-ion battery. The battery 40 stores electric power introduced from a charger 200 outside the vehicle 10 and is discharged with the electric power for traveling of the vehicle 10. The battery sensors 42 include, for example, the current sensor, the voltage sensor, and the temperature sensor. The battery sensors 42 detect, for example, a current value, a voltage value, and a temperature of the battery 40. The battery sensors 42 output the detected current value, voltage value, and temperature and the like to the control unit 36. When the calculated SOC is output to the data generation device 52, the control unit 36 outputs the current value, the voltage value, the temperature, and the like output by the battery sensors 42 to the data generation device 52.

The data generation device 52 includes a calculator and a storage. Initial information about the battery 40 is stored in the storage. The initial information about the battery 40 includes a name of a manufacturer of the battery, a manufacturing date, a use start date (a date when the battery 40 has been mounted in the vehicle 10), a device composition, a design capacity, and a design voltage. The initial information about the battery 40 is information that is fixed and does not fluctuate. A period elapsed from the use start date is an example of a period during which the battery 40 has been mounted in the vehicle 10.

The data generation device 52 adds 1 to a cycle count when the charge execution information has been output by the control unit 36. The data generation device 52 calculates a charge capacity and a full charge capacity of the battery 40 using the current value, the voltage value, the temperature, the SOC, and the like of the battery 40 output by the control unit 36. The data generation device 52 generates collected data 152 on the basis of the initial information stored in the storage, the cycle count, and the information output by the control unit 36. The data generation device 52 includes a battery-equipped vehicle model, which is a vehicle model of the vehicle 10, in the collected data 152. The data generation device 52 outputs the collected data 152, which has been generated, to the communication device 54. The battery-equipped vehicle model is an example of vehicle information.

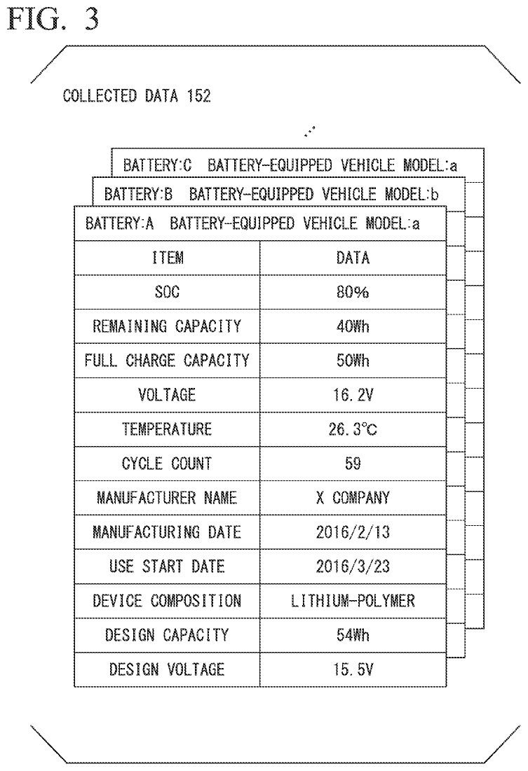

FIG. 3 is a diagram showing an example of the collected data 152. As shown in FIG. 3, items of the collected data 152 include “SOC,” “remaining capacity,” “full charge capacity,” “voltage,” “temperature,” “cycle count,” “manufacturer name,” “manufacturing date,” “use start date,” “device composition,” “design capacity,” and “design voltage.” Among the above items, use state information of the battery 40 such as the “SOC,” the “remaining capacity,” the “full charge capacity,” the “voltage,” the “temperature,” and the “cycle count” is data that is updated at any time. The initial information of the items of the “manufacturer name,” the “manufacturing date,” the “use start date,” the “device composition,” the “design capacity,” and the “design voltage” is data stored at the time of manufacturing or when the battery 40 is mounted in the vehicle 10. The use state information and the initial information are examples of secondary battery information. The collected data 152 also includes a type of battery (“A,” “B,” “C,” or the like) and a battery-equipped vehicle model (“a,” “b,” or the like).

The “SOC” is an item indicating an SOC of the battery 40 mounted in the vehicle 10, the “remaining capacity” is an item indicating the remaining capacity of the battery 40, and the “full charge capacity” is an item indicating the full charge capacity of the battery 40. The SOC, the remaining capacity, and the full charge capacity have the following relationship (1).

“SOC”×“full charge capacity”=“remaining capacity” (1)

The “voltage” is an item indicating a voltage of the battery 40 and the “temperature” is an item indicating a temperature of the battery 40. As the “voltage,” a value detected by the voltage sensor provided in the battery sensor 42 is used. As the “temperature,” a value detected by the temperature sensor provided in the battery sensor 42 is used. The “cycle count” is data of counting when the charging execution information has been output by the data generation device 52 and indicates the number of times the battery 40 has been charged.

The “manufacturer name” is an item indicating a name of a manufacturer that manufactured the battery 40. The “manufacturing date” is an item indicating the date on which the battery 40 was manufactured. The “use start date” is an item indicating a date when the battery 40 was mounted in the vehicle 10 and the use of the battery 40 was started. The “device composition” is an item indicating a composition constituting the battery 40. The “design capacity” is an item indicating a design value of a capacity when the battery 40 is used and the “design voltage” is an item indicating a design value of a voltage when the battery 40 is used.

The data generation device 52 generates in-vehicle battery information, which is information of the battery 40, in addition to the collected data 152. The in-vehicle battery information includes data such as the SOC, the current value, the voltage value, the temperature, the remaining capacity, the full charge capacity, and the maximum cruising distance of the battery 40. The above data may be displayed numerically or may be displayed as icons or the like. Also, an accurate numerical value may be displayed or a numerical value different from the accurate numerical value such as a numerical value obtained by correcting the accurate numerical value may be displayed.

The communication device 54 includes a wireless module for connecting to a cellular network or a Wi-Fi network. The communication device 54 acquires the collected data 152 output by the data generation device 52 and transmits the collected data 152 to the information processing device 100 via the network NW shown in FIG. 1. Also, the communication device 54 receives the information transmitted by the information processing device 100 via the network NW. The communication device 54 outputs the received information to the display device 60.

The display device 60 includes, for example, a display 62 and a display controller 64. The display 62 is, for example, a multi-information display (MID), and displays information based on control of the display controller 64. The display controller 64 causes the display 62 to display the in-vehicle battery information of the in-vehicle battery or the battery 40 other than the in-vehicle battery in accordance with the information output by the control unit 36 and the communication device 54.

The charging port 70 is provided oriented toward outside of the vehicle body of the vehicle 10. The charging port 70 is connected to the charger 200 via a charging cable 220. The charging cable 220 includes a first plug 222 and a second plug 224. The first plug 222 is connected to the charger 200 and the second plug 224 is connected to the charging port 70. The electricity supplied from the charger 200 is supplied to the charging port 70 via the charging cable 220.

Also, the charging cable 220 includes a signal cable attached to a power cable. The signal cable mediates communication between the vehicle 10 and the charger 200. Therefore, each of the first plug 222 and the second plug 224 is provided with a power connector and a signal connector.

The converter 72 is provided between the charging port 70 and the battery 40. The converter 72 converts a current introduced from the charger 200 via the charging port 70, for example, an AC, into a DC. The converter 72 outputs the DC obtained in the conversion to the battery 40.

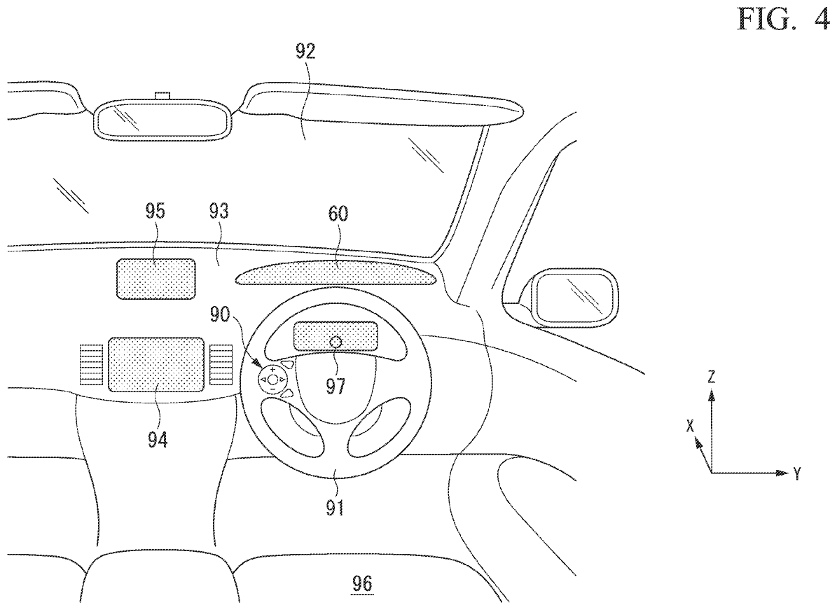

FIG. 4 is a diagram showing an example of a configuration of a cabin of the vehicle 10. As shown in FIG. 4, the vehicle 10 includes, for example, the display device 60, a steering switch 90, a steering wheel 91 that controls the steering of the vehicle 10, a front windshield 92 that separates the outside and the inside of the vehicle, an instrument panel 93, a first display device 94, a second display device 95, and an in-wheel area display 97.

The display device 60 is arranged, for example, in a meter panel unit including an instrument such as a vehicle speedometer provided on the instrument panel 93 in front of the driver's seat. The steering switch 90 is arranged on the steering wheel 91. The steering switch 90 is an input device arranged at a position where an operation by the driver's finger holding the steering wheel 91 is possible. For example, the steering switch 90 outputs a signal based on a pressing operation by the driver's finger and outputs a signal for switching the display of the display device 60. The display controller 64 (FIG. 2) of the display device 60 switches the display of the display 62 in accordance with the signal output by the steering switch 90.

The front windshield 92 is a member having light transmission. The first display device 94 and the second display device 95 are provided near the left front of the driver's seat 96 on the instrument panel 93 within the cabin.

The first display device 94 is, for example, a liquid crystal display arranged on a central portion of the instrument panel 93. The first display device 94 is, for example, a touch panel that receives an input operation by the contact of an operator's finger. For example, the first display device 94 displays an image corresponding to a navigation process executed by a navigation device (not shown) mounted in the vehicle 10 or displays a video of the other party and the like on a videophone.

The second display device 95 is a liquid crystal display arranged above the first display device 94 on the instrument panel 93. The second display device 95 is, for example, a touch panel that receives an input operation by the contact of the operator's finger. The second display device 95 is arranged at a position where visual recognition of the driver of the vehicle 10 is easy as compared with the first display device 94. Compared with the first display device 94, the second display device 95 is arranged at a position allowing visual recognition by the driver who is driving the vehicle 10 with a smaller movement of a line of sight. The second display device 95 is arranged, for example, at a position closer to the front windshield 92 than the first display device 94, a position closer to a gaze range in front of the driver in an appropriate driving posture than the first display device 94, or the like. The second display device 95 displays a television program, performs DVD reproduction, and displays content such as a downloaded movie.

For example, the in-wheel area display 97 is arranged above the steering wheel 91. For example, the vehicle speed of the vehicle 10 or the like is displayed on the in-wheel area display 97. The display device 60 may be arranged at another position such as a position where the in-wheel area display 97 is arranged. Display content of display devices such as the display device 60, the first display device 94, the second display device 95, and the in-wheel area display 97 may be switched appropriately.

### [Information Processing Device 100]

The information processing device 100 shown in FIG. 1 includes, for example, a communication unit (a reception unit) 110, an analysis unit 120, a provision unit 130, and a storage 150. The analysis unit 120 and the provision unit 130 are implemented by, for example, a hardware processor such as a central processing unit (CPU) executing a program (software). Some or all of these components may be implemented by hardware (including a circuit unit; circuitry) such as a large-scale integration (LSI) circuit, an application specific integrated circuit (ASIC), a field-programmable gate array (FPGA), or a graphics processing unit (GPU) or may be implemented by software and hardware in cooperation. The program may be prestored in a storage device (a non-transitory storage medium) such as a hard disk drive (HDD) or a flash memory or may be stored in a removable storage medium (a non-transitory storage medium) such as a DVD or CD-ROM and installed when the storage medium is mounted in a drive device. The storage 150 is implemented by the storage device described above.

Under the assumption that a process of the information processing device 100 is performed, each of the plurality of vehicles 10 generates the collected data 152 (FIG. 3) and transmits the collected data 152 (FIG. 3) to the information processing device 100 using the communication device 54. The vehicle 10 may generate the collected data 152 every prescribed time period, for example, every hour or every day or may generate the collected data 152 on the basis of an instruction of the user of the vehicle 10 and the like. Also, the vehicle 10 may transmit the collected data 152 in response to a request of the information processing device 100. Also, the vehicle 10 may be configured to transmit the collected data 152 when a prescribed condition is satisfied, for example, when the load of the battery exceeds a certain amount, or when the SOC or the full charge capacity falls below a prescribed value. Also, the vehicle 10 may transmit the collected data 152 at any one or more of the above timings.

The communication unit 110 receives the collected data 152 transmitted by each of the plurality of vehicles 10. The communication unit 110 outputs the collected data 152, which has been received, to the analysis unit 120.

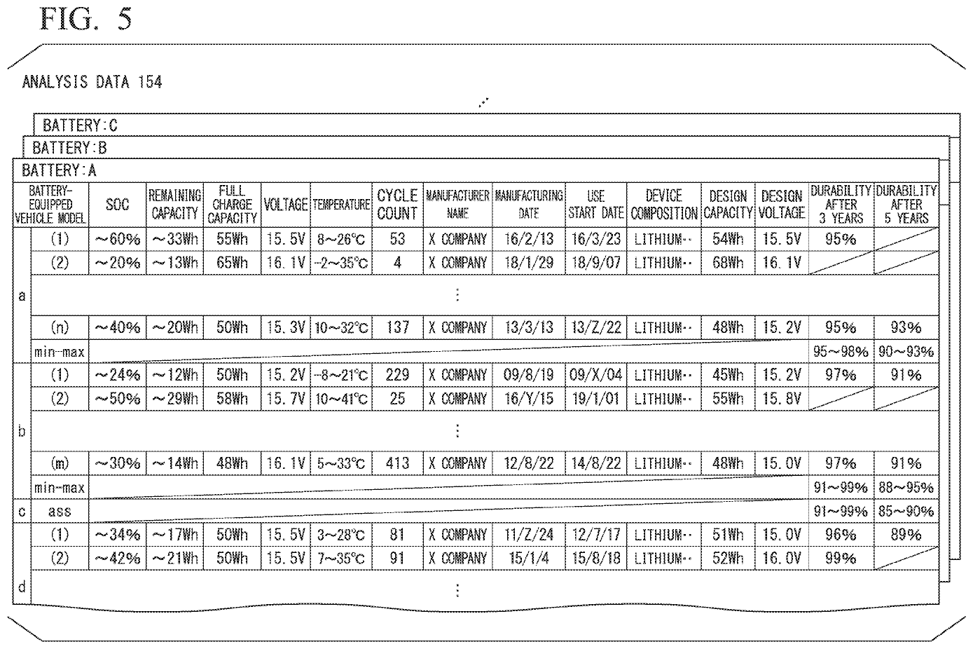

The analysis unit 120 generates analysis data by analyzing a large number of pieces of collected data 152 received by the communication unit 110 and stored in the storage 150. FIG. 5 is a diagram showing an example of analysis data 154. The analysis data 154 is data obtained by aggregating and analyzing a plurality of pieces of collected data 152 for each type of battery 40. Thus, the analysis data 154 is generated for each type of battery. The analysis data 154 is an example of analysis information.

For example, the analysis unit 120 classifies and summarizes items included in the plurality of pieces of collected data 152 transmitted from the vehicle 10 in which the battery A is mounted as the data of the battery “A” according to each battery-equipped vehicle model. In the example of FIG. 5, the analysis unit 120 summarizes n pieces of collected data 152 from (1) to (n) as items of the battery “A” mounted in a battery-equipped vehicle model “a.” The analysis unit 120 summarizes m pieces of collected data 152 from (1) to (m) as items of the battery “A” mounted in a battery-equipped vehicle model “b.”

Because the collected data 152 has not been obtained for the battery “A” mounted in the battery-equipped vehicle model “c,” the analysis unit 120 does not summarize data for each item of the battery “A” mounted in the battery-equipped vehicle model “c.” Regarding the battery “A” mounted in the vehicle 10 of another battery-equipped vehicle model, the analysis unit 120 summarizes the collected data 152 as in the battery-equipped vehicle models “a” and “b” within a range in which the collected data 152 has been obtained.

In the analysis unit 120, the collected data 152 is summarized and the analysis data 154 is generated as in the battery “A” with respect to batteries other than the battery “A,” i.e., batteries “B,” “C,” and the like. The analysis unit 120 stores the analysis data 154, which has been generated, in the storage 150 and the analysis unit 120 reads the analysis data 154 from the storage 150 and updates the analysis data 154 when the collected data 152 has been received.

Further, the analysis unit 120 digitizes an actual value of a width of durability after each of a plurality of types of prescribed periods, specifically, two types of periods such as 3 years or 5 years, with respect to a relationship between a type of battery and a battery-equipped vehicle model. The durability refers to a ratio of a full charge capacity of the battery 40 at a determination time point to a full charge capacity of the battery 40 at a reference time point. For example, the durability after 3 years is a ratio of a full charge capacity of the battery 40 when 3 years have elapsed since the battery 40 was mounted in the vehicle 10 to a full charge capacity of the battery 40 when the battery 40 was unused as a new product. The reference time point may be a manufacturing date of the battery 40, a date when the battery 40 was mounted in the vehicle 10, or any of several days before and after these dates. Alternatively, the reference time point may be any date between the manufacturing date of the battery 40 and the date when the battery 40 was mounted in the vehicle 10 or may be another date.

In the example shown in FIG. 5, the minimum and maximum values of the durability of the battery “A” mounted in the battery-equipped vehicle model “a” after 3 years is 95% and 98%, respectively, and the minimum and maximum values of the durability thereof after 5 years is 90% and 93%, respectively. The minimum and maximum values of the durability of the battery “A” mounted in the battery-equipped vehicle model “b” after 3 years is 91% and 99%, respectively, and the minimum and maximum values of the durability thereof after 5 years is 88% and 95%, respectively.

The analysis unit 120 estimates the durability of a combination of a battery and a battery-equipped vehicle model for which the collected data 152 was not obtained using the durability of another combination of a battery and a battery-equipped vehicle model. In the example shown in FIG. 5, the analysis unit 120 estimates the durability after 3 years and the durability after 5 years for all batteries A for which the collected data 152 has been obtained as the durability after 3 years and the durability after 5 years for the battery “A” mounted in the battery-equipped vehicle model “c,” respectively.

The analysis unit 120 generates the provision data 156 related to the performance at the time of reuse of the battery 40 on the basis of the analysis data 154, which has been generated, when an information provision request has been transmitted from the terminal device 300 and/or the used vehicle sales business server 400. The provision data is an example of provision information.

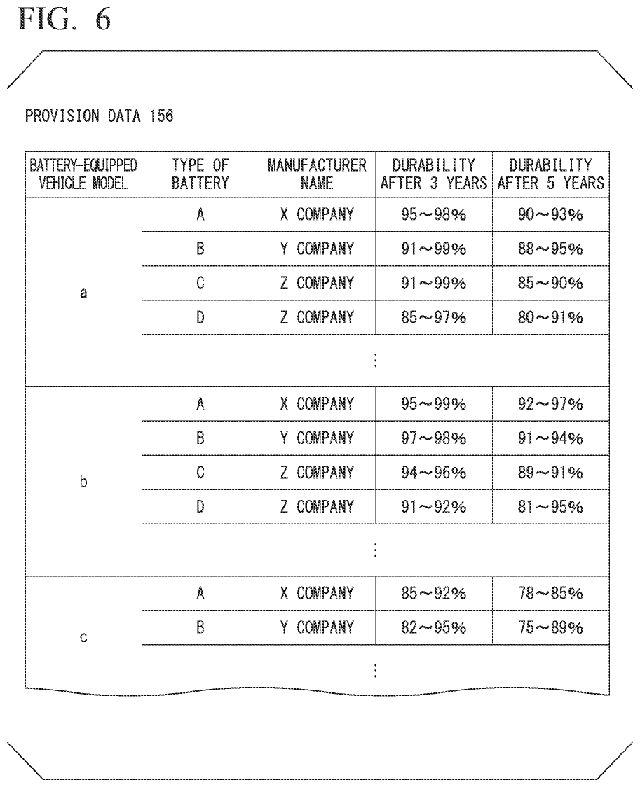

FIG. 6 is a diagram showing an example of the provision data 156. As shown in FIG. 6, the provision data 156 is data showing the durability after 3 years and the durability after 5 years for each combination of the type of battery and the battery-equipped vehicle model. Here, the analysis unit 120 obtains the durability after 3 years and the durability after 5 years for each combination of the battery 40 and the battery-equipped vehicle model from data classified for each battery 40 in the analysis data 154.

When the analysis data 154 includes the durability after 3 years and the durability after 5 years for each combination of a battery 40 and a battery-equipped vehicle model, the analysis unit 120 uses numerical values thereof as they are as the provision data 156. When the analysis data 154 does not include the durability after 3 years and the durability after 5 years for each combination of the battery 40 and the battery-equipped vehicle model, the analysis unit 120 uses numerical values estimated using the durability of another combination of a battery and a battery-equipped vehicle model as the provision data 156. The analysis unit 120 thus collectively generates the durability after 3 years and the durability after 5 years as the provision data 156. The analysis unit 120 stores the generated provision data 156 in the storage 150 and outputs the provision data 156 to the provision unit 130.

The provision data 156 is, for example, information about the performance of the battery 40 at the time of reuse. Although the performance of the battery 40 at the time of reuse is durability after 3 years and durability after 5 years in the first embodiment, the performance of the battery 40 at the time of reuse may be other information. For example, the performance of the battery 40 at the time of reuse may be durability after the elapse of a period other than 3 or 5 years or may be information other than durability, for example, a full charge capacity, a cycle count, or the like. Alternatively, the provision data 156 may be information for obtaining the performance of the battery 40 at the time of reuse and may be, for example, data of each item included in the analysis data 154.

The provision unit 130 transmits the provision data 156 output by the analysis unit 120 to the terminal device 300 or the used vehicle sales business server 400 that has transmitted the information provision request using the communication unit 110. The provision unit 130 may be configured to transmit the provision data 156 to a device other than the device that has transmitted the information provision request.

The terminal device 300 is, for example, a portable terminal carried by the user U and includes a communication unit, a touch panel, an application execution unit, a display controller, and a storage. The communication unit communicates with the information processing device 100 and other external devices via, for example, a network such as a LAN, a WAN, or the Internet. The touch panel displays various types of information on the basis of control of the display controller, displays various types of keys and/or buttons and the like, and receives the input of the user U by the above operations, for example, an input for transmitting an information provision request to the information processing device 100. The user U can transmit the information provision request to the information processing device 100 using the terminal device 300.

The application execution unit is implemented by executing a reuse battery information application stored in the storage. For example, the application execution unit communicates with the information processing device 100 via the communication unit and the network, receives the provision data 156 transmitted by the information processing device 100 using the communication unit, and outputs the provision data 156 to the display controller. The display controller causes the touch panel to display information indicating the provision data 156 output by the application execution unit. The application execution unit may cause the information indicating the provision data 156 to be displayed in any way. For example, the information indicating the provision data 156 may be displayed in a text format or the like or may be displayed in a graphic format or the like using an icon or the like.

The used vehicle sales business server 400 includes a communication unit, an inputter, a control unit, a display controller, and a display. The communication unit communicates with the information processing device 100 and other external devices via, for example, a network such as a LAN, a WAN, or the Internet. The inputter displays various types of keys and/or buttons and the like, and receives the input of the operator of the used vehicle sales business server 400 by the above operations, for example, an input for transmitting an information provision request to the information processing device 100. The used vehicle sales business operator can transmit the information provision request to the information processing device 100 using the used vehicle sales business server 400. The display displays various types of information on the basis of the control of the display controller.

For example, the control unit communicates with the information processing device 100 via the communication unit and the network, receives the provision data 156 transmitted by the information processing device 100 using the communication unit, and outputs the provision data 156 to the display controller. The display controller causes the display to display information indicating the provision data 156 output by the control unit. The display controller may cause the information indicating the provision data 156 to be displayed in any way. For example, the information indicating the provision data 156 may be displayed in a text format or the like or may be displayed in a graphic format or the like using an icon or the like.

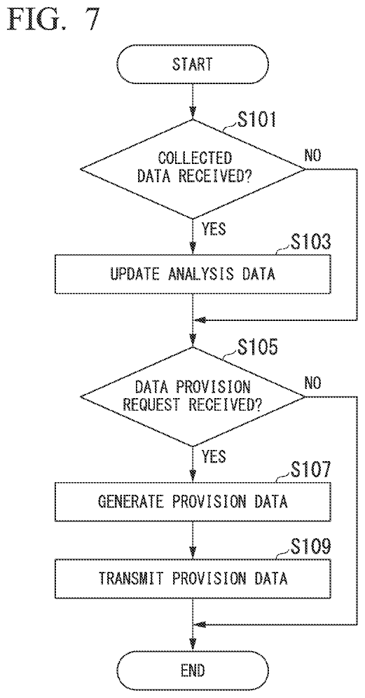

Next, the process in the information processing device 100 will be described. FIG. 7 is a flowchart showing an example of a process executed by the information processing device 100. The analysis unit 120 provided in the information processing device 100 first determines whether or not the communication unit 110 has received the collected data 152 transmitted by the vehicle 10 (step S101).

When the communication unit 110 determines that the collected data 152 has not been received, the analysis unit 120 proceeds to the processing of step S105. When the communication unit 110 determines that the collected data 152 has been received, the analysis unit 120 reads the analysis data 154 stored in the storage 150. The analysis unit 120 updates the analysis data 154, which has been read, on the basis of the collected data 152 received by the communication unit 110 (step S103). The analysis unit 120 stores the analysis data 154, which has been updated, in the storage 150. The information processing device 100 expands the analysis data 154 by updating the analysis data 154 every time the collected data 152 is acquired.

Subsequently, the analysis unit 120 determines whether or not the communication unit 110 has received the information provision request transmitted by the terminal device 300 or the used vehicle sales business server 400 (step S105). When it is determined that the communication unit 110 has not received the information provision request, the analysis unit 120 ends the process shown in FIG. 7.

When it is determined that the communication unit 110 has received the information provision request, the analysis unit 120 reads the analysis data 154 stored in the storage 150 and generates the provision data 156 using the analysis data 154 that has been read (step S107). After the provision data 156 is generated, the analysis unit 120 stores the analysis data 154, which has been read, in the storage 150 as it is.

Subsequently, the provision unit 130 transmits the analysis data 154 generated by the analysis unit 120 to the terminal device 300 or the used vehicle sales business server 400, which has transmitted the information provision request, using the communication unit 110 (step S109). Thus, the information processing device 100 ends the process shown in FIG. 7.

The terminal device 300 or the used vehicle sales business server 400, which has received the provision data transmitted by the information processing device 100, provides information of the provision data to the user U or the used vehicle sales business operator. For example, when the user U has transmitted an information provision request to the information processing device 100 using the terminal device 300, the information processing device 100 transmits the provision data 156 to the terminal device 300. When the used vehicle sales business operator has transmitted an information provision request to the information processing device 100 using the used vehicle sales business server 400, the information processing device 100 transmits the provision data 156 to the used vehicle sales business server 400.

For example, in the terminal device 300 to which the provision data 156 has been transmitted by the information processing device 100, the display controller provided in the terminal device 300 causes the touch panel to display an image showing the information of the provision data 156. As the image showing the information of the provision data 156, for example, there is an image in which the durability after 3 years and the durability after 5 years included in the provision data 156 are displayed in a text format with a heading, an icon, or the like. Thus, the information about the performance of the battery 40 at the time of reuse included in the provision data 156 is provided to the user U and/or the used vehicle sales business operator.

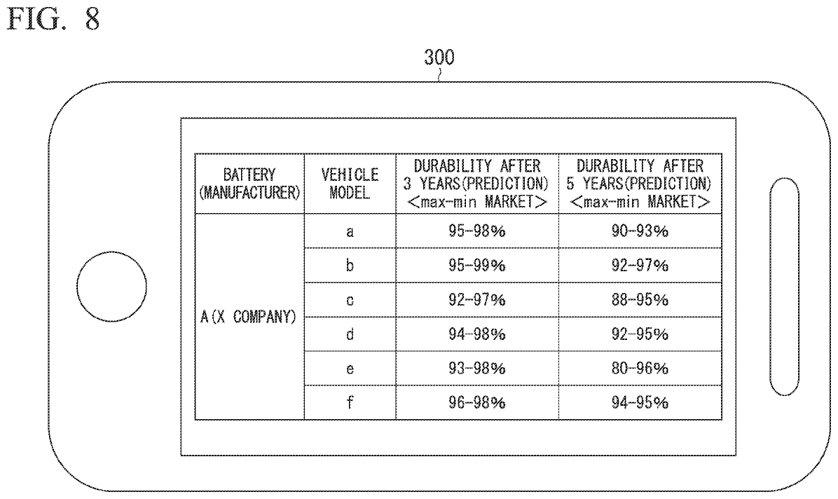

FIG. 8 is a diagram showing an example of a screen displayed on the terminal device 300. As shown in FIG. 8, on the display of the terminal device 300, the durability after 3 years and the durability after 5 years of the battery 40 are displayed in a matrix in a text format for each vehicle model as predicted values. Although the durability after 3 years and the durability after 5 years for the battery A are displayed in the example shown in FIG. 8, the durability after 3 years and the durability after 5 years for other types of batteries are displayed by redisplaying the screen.

The information processing device 100 of the first embodiment generates analysis data 154 on the basis of states of use of batteries 40 in a plurality of vehicles 10, generates provision data 156 including the durability after 3 years and the durability after 5 years related to the performance of the battery 40 at the time of reuse from the analysis data 154, and transmits the provision data 156 to the user U, the used vehicle sales business operator, and/or the like. Thus, the user U, the used vehicle sales business operator, and/or the like can obtain information of the performance of the battery 40 at the time of reuse, such as the durability after 3 years and the durability after 5 years.

### Second Embodiment

Next, a second embodiment will be described. In an information processing system 1 of the second embodiment, even if a vehicle 10 equipped with a battery 40 is resold as a used vehicle and its owner changes, information about the performance at the time of reuse such as durability after 3 years and durability after 5 years is provided. A data configuration of the second embodiment is mainly different from that of the first embodiment and differences from the first embodiment will be mainly described in the second embodiment.

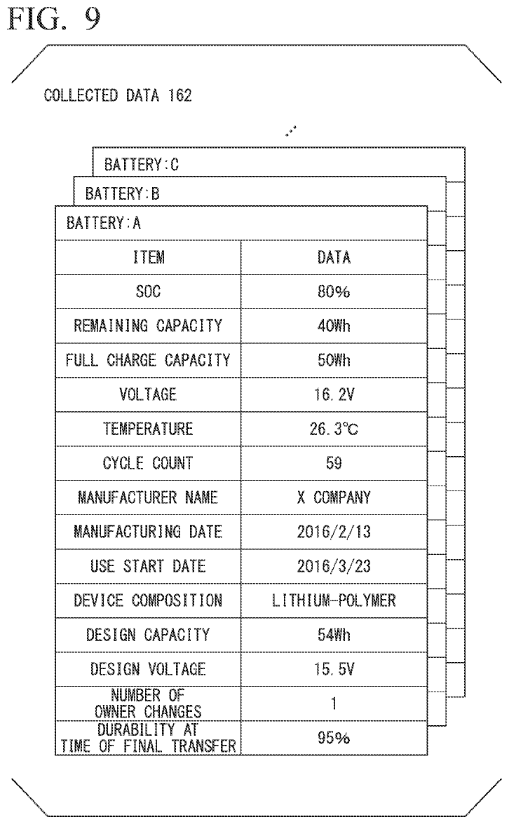

FIG. 9 is a diagram showing an example of collected data 162 of the second embodiment. As shown in FIG. 9, in the collected data 162 in the second embodiment, in addition to each item of the collected data 152 in the first embodiment shown in FIG. 3, items of the number of owner changes and the durability at the time of the final transfer are added. A loading history item indicates the number of times the vehicle 10 has been resold as a used vehicle or the like and the owner has changed.

When the number of owner changes is “0,” this indicates that the vehicle 10, which is a new vehicle, is equipped with the battery 40. When the number of owner changes is “1,” this indicates that the vehicle 10 has been sold as a used vehicle once and the battery 40 is mounted in the vehicle 10 whose owner has changed once.

The item of durability at the time of the final transfer indicates a full charge capacity of the battery 40 when the owner last retreated. In the collected data 162, a date when a start date of use of the vehicle 10 of a current owner instead of a start date of use in another vehicle is stored as the item of “use start date.”

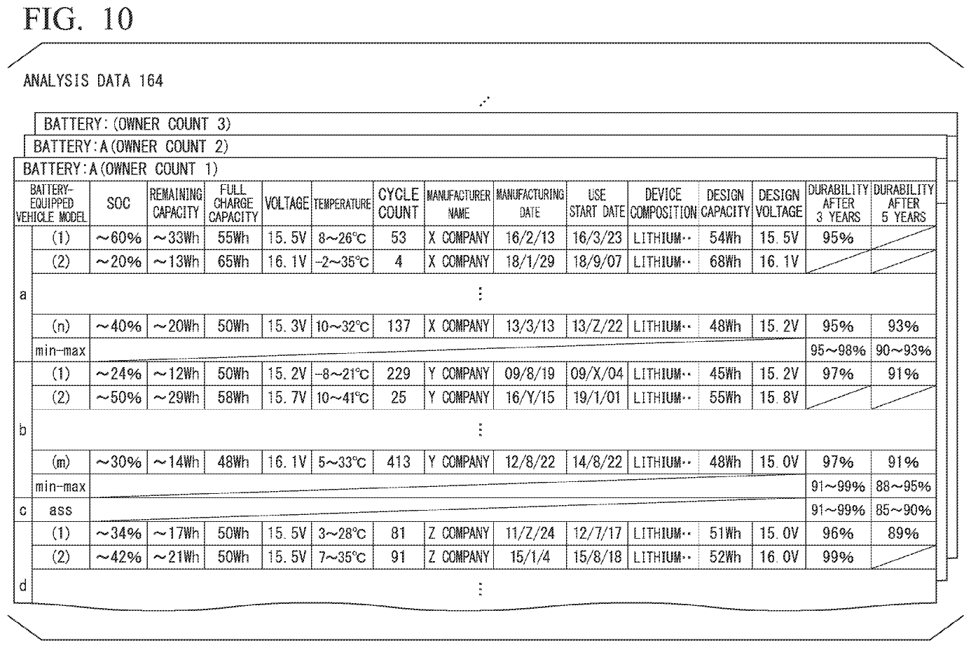

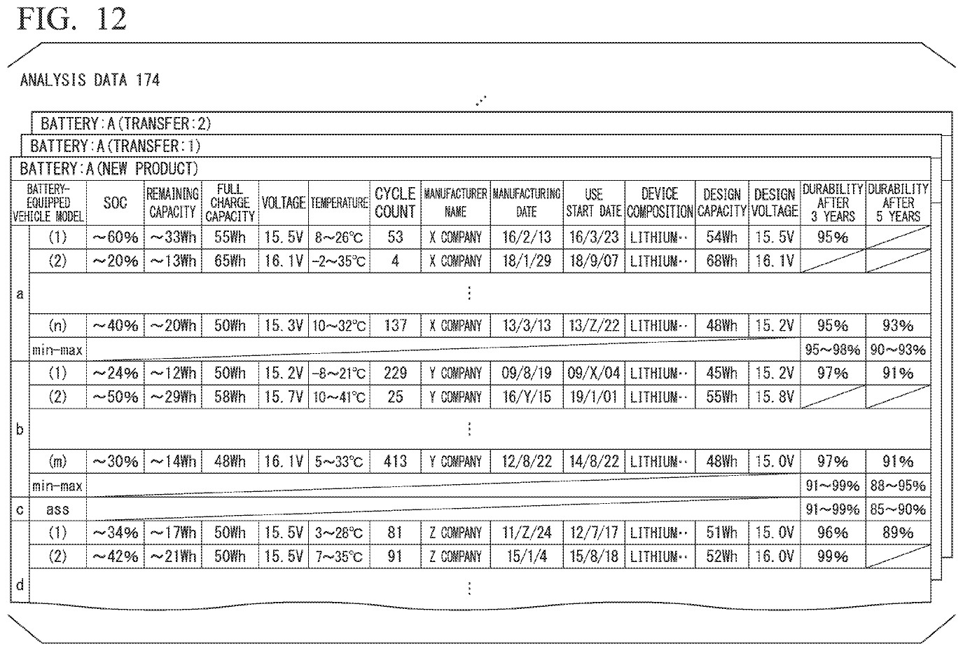

FIG. 10 is a diagram showing an example of analysis data 164 of the second embodiment. As shown in FIG. 12, the analysis data 164 in the second embodiment is generated as different data for each number of times the owner has been changed for the same type of battery 40. In FIG. 12, the analysis data 164 of a battery “A” is displayed. An analysis unit 120 generates the analysis data 164 for each of “owner count 1,” “owner count 2,” “owner count 3,” and the like as the data of the battery “A.” Although not shown in FIG. 10, analysis data is similarly generated for each owner count of the vehicle 10 in batteries “B,” “C,” “D,” and the like. The owner count is a value obtained by adding 1 to the number of owner changes.

The analysis unit 120 generates the provision data as in the first embodiment on the basis of the analysis data 164 that has been generated. A provision unit 130 transmits the provision data generated by the analysis unit 120 to a terminal device 300 of a user U and/or a used vehicle sales business server 400 of a used vehicle sales business operator.

The information processing device 100 of the first embodiment generates analysis data 154 on the basis of a state of use of the battery 40 in the plurality of vehicles 10 and the like, generates provision data including the durability after 3 years and the durability after 5 years regarding the performance of the battery 40 at the time of reuse of the battery 40 from the analysis data 154, and transmits the provision data to the user U, the used vehicle sales business operator, and/or the like. Thus, the user U, the used vehicle sales business operator, and/or the like can obtain information about the performance of the battery 40 at the time of reuse, such as the durability after 3 years and the durability after 5 years. The provision data is data for each owner count. Thus, it is possible to confirm a difference in the owner count and the like. Consequently, it is possible to obtain information to which the difference in the owner count and the like are added with respect to information about the performance of the battery 40 at the time of reuse, such as the durability after 3 years and the durability after 5 years. Although the analysis data 164 is generated for each owner count in the second embodiment, the analysis data 164 may be generated for each owner to generate and provide the provision data.

### Third Embodiment

Next, a third embodiment will be described. An information processing system 1 of the third embodiment provides information about the performance of a battery 40 at the time of reuse such as durability after 3 years and durability after 5 years even after the battery 40 is transferred from a vehicle 10 to another vehicle 10. A data configuration of the third embodiment is mainly different from that of the first embodiment as in the second embodiment and differences from the first embodiment will be mainly described in the third embodiment.

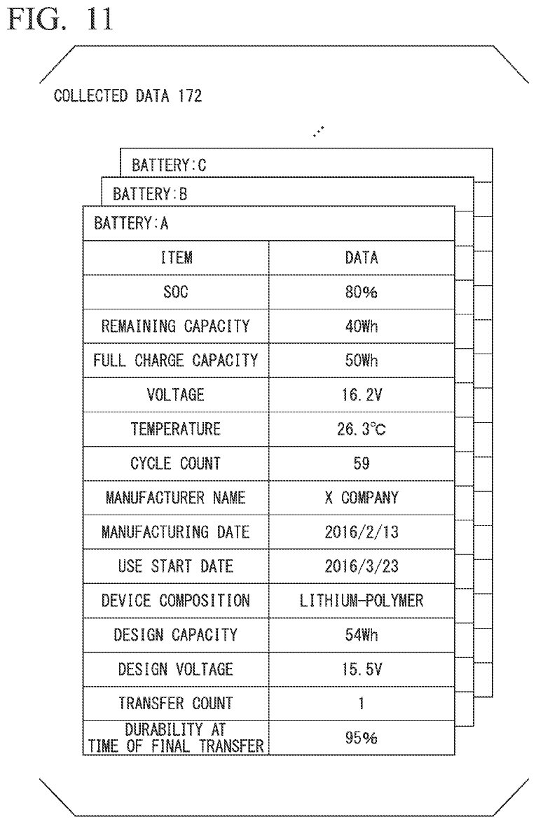

FIG. 11 is a diagram showing an example of collected data 172 of the third embodiment. As shown in FIG. 11, in the collected data 172 of the third embodiment, in addition to each item of the collected data 152 of the first embodiment shown in FIG. 3, a transfer count and the durability at the time of the final transfer are added. A loading history item indicates the number of times the battery 40 has been transferred between vehicles. When the transfer count is “0,” this indicates that a battery 40 of a new product is mounted. When the transfer count is “1,” this indicates that the battery 40 has a history of transfers between two or more vehicles 10 and the vehicle 10 currently equipped with the battery 40 is equipped with a used battery 40.

The item of durability at the time of the final transfer indicates a full charge capacity of the battery 40 when the battery 40 was last transferred between the vehicles 10. In the collected data 172, a start date of use of the battery mounted in a current vehicle 10 instead of a start date of use in another vehicle is stored as the item of “use start date.”

FIG. 12 is a diagram showing an example of analysis data 174 of the third embodiment. As shown in FIG. 12, the analysis data 174 in the third embodiment is also generated as different data for each transfer count for the same type of battery 40. In FIG. 12, the analysis data 174 of a battery “A” is displayed. An analysis unit 120 generates the analysis data 174 for each item of “new product,” “transfer count: 1,” “transfer count: 2,” and the like as data of the battery “A.” Although not shown in FIG. 12, analysis data is similarly generated for each transfer count with respect to batteries “B,” “C,” “D,” and the like.

The analysis unit 120 generates provision data as in the first embodiment on the basis of the analysis data 174 that has been generated. A provision unit 130 transmits the provision data generated by the analysis unit 120 to a terminal device 300 of a user U and/or a used vehicle sales business server 400 of a used vehicle sales business operator.

The information processing device 100 of the first embodiment generates analysis data 154 on the basis of a state of use of the battery 40 in the plurality of vehicles 10 and the like, generates provision data including the durability after 3 years and the durability after 5 years regarding the performance of the battery 40 at the time of reuse of the battery 40 from the analysis data 154, and transmits the provision data to the user U, the used vehicle sales business operator, and/or the like. Thus, the user U, the used vehicle sales business operator, and/or the like can obtain information about the performance of the battery 40 at the time of reuse, such as the durability after 3 years and the durability after 5 years. The provision data is data for each transfer count of the battery. Thus, it is possible to confirm a difference between the used product and the new product as the battery 40, a difference in a transfer count when the battery 40 is a used product, and the like. Consequently, it is possible to obtain information to which a difference between the used product and the new product and the like are added with respect to information about the performance of the battery 40 at the time of reuse, such as the durability after 3 years and the durability after 5 years.

Also, the information processing device 100 may transmit the durability after 3 years and the durability after 5 years to another device, for example, a communication device of the vehicle 10. In the vehicle 10, information about the performance at the time of reuse as shown in FIG. 8 may be displayed on the display device 60 of the vehicle 10. The vehicle 10 may display information associated with the collected data 152. As for the information associated with the collected data 152, for example, each item of the collected data 152 may be displayed in a text format or the like, or information obtained from each item of the collected data 152 may be displayed in a text format or a format using an icon.

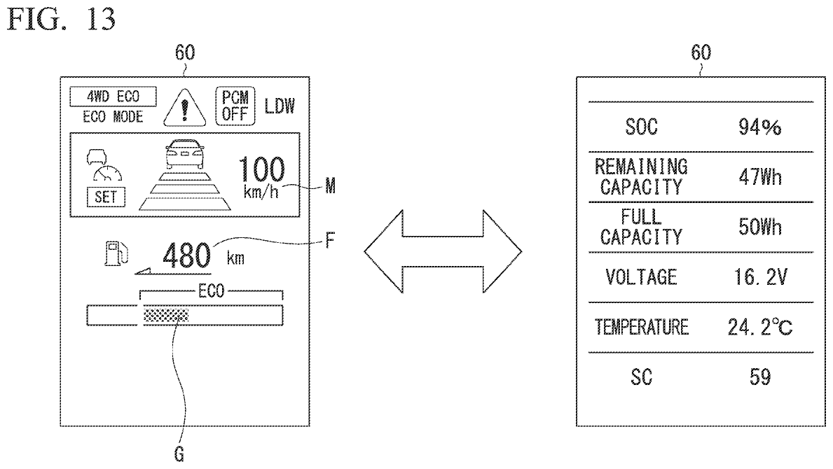

When the information associated with the collected data 152 is displayed by the display device 60, the vehicle 10 may be configured to be able to display the information while switching a display screen to a screen for displaying other information. FIG. 13 is a diagram showing an example of an image displayed on the display device 60. For example, the display device 60 displays an image showing traveling information M, the maximum cruising distance F, and SOC information G of the battery 40 as shown on the left side of FIG. 13.

When the steering switch 90 is operated and a signal is transmitted to the display device 60 while the image on the left side of FIG. 13 is displayed, use state information within the collected data 152 is displayed in a text format as shown in the image shown on the right side of FIG. 13. Also, “SC” in an image shown on the right side of FIG. 13 denotes the cycle count. When the steering switch 90 is operated and a signal is transmitted to the display device 60 while the image on the right side of FIG. 13 is displayed, the image shown on the left side of FIG. 13 is displayed. In this way, the display of the display device 60 may be switched according to an operation on the steering switch 90.

Although the information processing device 100 may provide the user U and/or the used vehicle sales business operator with information about the durability after 3 years and the durability after 5 years as the provision data 156, other information about the battery 40 may be provided as the provision data 156. For example, data obtained by statistically summarizing the collected data 152 transmitted by the vehicle 10 may be used as the provision data 156 or data appropriately selected from the data obtained by statistically summarizing the collected data 152 may be used as the provision data 156. Also, for each item of the collected data 152 and the like, conditionally summarized data or processed data thereof may be used as the provision data 156.

The present invention has been described above using the above embodiments, but the technical scope of the present disclosure is not limited to the scope described in the above embodiments. Those skilled in the art can make various changes or improvements to the above embodiments. It is obvious from the description of the claims that the changes or improvements may be included in the technical scope of the present invention.

### INDUSTRIAL APPLICABILITY

According to the present invention, an information processing device includes a reception unit configured to receive vehicle information about a vehicle equipped with a secondary battery and secondary battery information about the secondary battery transmitted from the vehicle; an analysis unit configured to generate analysis information by analyzing a relationship between the vehicle information and each type of the secondary battery information; and a provision unit configured to provide provision information based on the analysis information.

The information processing device of the present invention is particularly useful when it is possible to obtain information about the performance of a secondary battery at the time of reuse.

### REFERENCE SIGNS LIST

1 Information processing system
10 Vehicle
12 Motor
14 Drive wheels
16 Brake device
20 Vehicle sensor
40 Battery
42 Battery sensors
52 Data generation device
54 Communication device
60 Display device
62 Display
64 Display controller
90 Steering switch
91 Steering wheel
92 Front windshield
93 Instrument panel
94 First display device
95 Second display device
96 Driver's seat
97 In-wheel area display
100 Information processing device
110 Communication unit (reception unit)
120 Analysis unit
130 Provision unit
150 Storage
152, 162, 172 Collected data
154,164,174 Analysis data,
156 Provision data
300 Terminal device
400 Used vehicle sales business server
NW Network
U User

What is claim is:

1.-10. (canceled)

11. An information processing device comprising:
a reception unit configured to receive vehicle information about a vehicle equipped with a secondary battery and secondary battery information about the secondary battery transmitted from the vehicle;
an analysis unit configured to generate analysis information by analyzing a relationship between the vehicle information and each type of the secondary battery information; and
a provision unit configured to provide provision information based on the analysis information,
wherein the analysis unit analyzes durability of the battery after each of a plurality of types of prescribed periods, and
wherein the provision unit simultaneously provides durability information after the plurality of types of prescribed periods.

12. The information processing device according to claim 11, wherein the secondary battery information includes information about at least one of a manufacturer of the secondary battery, the number of times the secondary battery has been charged, and a period during which the secondary battery has been mounted in the vehicle.

13. The information processing device according to claim 11, wherein the vehicle information includes a type of the vehicle.

14. The information processing device according to claim 11,
wherein the provision information is about durability of the secondary battery after a prescribed period, and
wherein the provision unit provides durability for the plurality of types of prescribed periods.

15. The information processing device according to claim 11,
wherein the vehicle information includes information about an owner of the vehicle, and
wherein, when the number of owners is two or more, the analysis unit generates the analysis information for each of the owners.

16. The information processing device according to claim 11, wherein, when the secondary battery has been mounted in a plurality of vehicles, the analysis unit generates the analysis information for each of the plurality of vehicles.

17. The information processing device according to claim 11, wherein the provision unit is able to provide the provision information while switching the provision information to other information.

18. An information processing method comprising:
receiving, by a computer, vehicle information about a vehicle equipped with a secondary battery and secondary battery information about the secondary battery transmitted from the vehicle;
generating, by the computer, analysis information by analyzing a relationship between the vehicle information and the secondary battery information;
providing, by the computer, provision information based on the analysis information;
analyzing, by the computer, durability of the battery after each of a plurality of types of prescribed periods; and
simultaneously providing, by the computer, durability information after the plurality of types of prescribed periods.

19. A computer-readable non-transitory storage medium storing a program for causing a computer to:
receive vehicle information about a vehicle equipped with a secondary battery and secondary battery information about the secondary battery transmitted from the vehicle;
generate analysis information by analyzing a relationship between the vehicle information and the secondary battery information;
provide provision information based on the analysis information;
analyze durability of the battery after each of a plurality of types of prescribed periods; and
simultaneously provide durability information after the plurality of types of prescribed periods.
